(19) United States
(12) Patent Application Publication
(10) Pub. No.: US 2025/0383610 A1
(43) Pub. Date: Dec. 18, 2025

(54) SYSTEM AND METHOD FOR OVERLAY MEASUREMENT USING DESIGN DATA AND DEEP LEARNING SEGMENTATION

(71) Applicant: KLA Corporation, Milpitas, CA (US)

(72) Inventor: Arpit Yati, Lucknow (IN)

(21) Appl. No.: 19/092,074

(22) Filed: Mar. 27, 2025

Related U.S. Application Data
(60) Provisional application No. 63/661,067, filed on Jun. 18, 2024.

(51) Int. Cl. G03F 7/00

(52) U.S. Cl. CPC G03F 7/70633; G03F 7/706841

(57) ABSTRACT

A method for overlay measuring using design data and deep learning segmentation is disclosed. The method may render selected design layers as rendered design images corresponding to each site of the design layers. A first design layer is rendered as a first rendered design image including a first site and a second design layer is rendered as a second rendered design image including a second site. The method may acquire measured images of a sample including multiple layers. The method may apply a deep learning model to the measured images to segment the measured images into a first segmented layer and a second segmented layer. The method may align a selected rendered design image with a corresponding segmented layer. The method may determine overlay shift between the first layer and the second layer based on alignment of the selected rendered design image and the corresponding segmented layer.

### CROSS-REFERENCE TO RELATED APPLICATION

The present application claims priority to U.S. Provisional Patent Application No. 63/661,067, filed Jun. 18, 2024, naming Arpit Yati as inventor, which is incorporated herein by reference in the entirety.

### TECHNICAL FIELD

The present disclosure relates to the field of overlay metrology and, in particular, to methods and systems for measuring overlay shifts between different layers of a semiconductor device using design data and deep learning (DL) segmentation of measured images.

### BACKGROUND

Demand for electronic logic and memory devices with ever-smaller footprints and features present a wide range of manufacturing challenges beyond fabrication at a desired scale. In semiconductor manufacturing, overlay measurements are critical for monitoring shifts between various layers to maximize yield. Logic devices have non-repeating patterns. This makes it especially difficult to measure overlay shift as it is difficult to define a specific pattern which needs to be searched and measured. Traditional methods involve standard edge detection techniques, which may not always be effective due to the complexity of under-layer structures and shrinking design rules. Existing methods face challenges in identifying structures within the die and extracting contours from scanning electron microscopy (SEM) images, especially when the top surface signal is poor. Therefore, it would be desirable to provide a system and method that address one or more of the shortfalls of the previous approaches identified above.

### SUMMARY

A method of overlay measurement is disclosed, in accordance with one or more embodiments of the present disclosure. In some aspects, the method includes receiving a user selection of a set of design layers for overlay shift calculation. In some aspects, the method includes rendering the set of selected design layers as a set of rendered design images corresponding to each site of the set of design layers, wherein a first design layer is rendered as a first rendered design image including a first site and at least a second design layer is rendered as a second rendered design image including a second site. In some aspects, the method includes acquiring one or more measured image of a sample including a plurality of layers, wherein the plurality of layers includes a first layer and a second layer. In some aspects, the method includes applying a deep learning model to the one or more measured images to segment the one or more measured images into at least a first segmented layer containing the first site and a second segmented layer containing the second site. In some aspects, the method includes aligning a selected rendered design image with a corresponding segmented layer. In some aspects, the method includes determining overlay shift between the first layer and the second layer based on alignment of the selected rendered design image and the corresponding segmented layer.

A system for overlay measurement is disclosed, in accordance with one or more embodiments of the present disclosure. In some aspects, the system includes an imaging sub-system configured to acquire one or more images of a sample. In some aspects, the system includes a controller including one or more processors configured to execute a set of program instructions stored in memory. In some aspects, the set of program instructions are configured to cause the one or more processors to receive a user selection of a set of design layers for overlay shift calculation. In some aspects, the set of program instructions are configured to cause the one or more processors to render the set of selected design layers as a set of rendered design images corresponding to each site of the set of design layers, wherein a first design layer is rendered as a first rendered design image including a first site and at least a second design layer is rendered as a second rendered design image including a second site. In some aspects, the set of program instructions are configured to cause the one or more processors to acquire one or more measured image of a sample including a plurality of layers, wherein the plurality of layers includes a first layer and a second layer. In some aspects, the set of program instructions are configured to cause the one or more processors to apply a deep learning model to the one or more measured images to segment the one or more measured images into at least a first segmented layer containing the first site and a second segmented layer containing the second site. In some aspects, the set of program instructions are configured to cause the one or more processors to align a selected rendered design image with a corresponding segmented layer. In some aspects, the set of program instructions are configured to cause the one or more processors to determine overlay shift between the first layer and the second layer based on alignment of the selected rendered design image with a corresponding segmented layer.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF THE DRAWINGS

The numerous advantages of the disclosure may be better understood by those skilled in the art by reference to the accompanying figures.

FIG. 1 illustrates a block diagram of a system for overlay measurements using design data and deep learning segmentation, in accordance with one or more embodiments of the present disclosure.

FIG. 2A illustrates a series of conceptual images depicting design layers in a design file and rendered design images corresponding with each layer, in accordance with one or more embodiments of the present disclosure.

FIG. 2B illustrates a series of conceptual images depicting an acquired SEM image and segmented layers of the SEM image, in accordance with one or more embodiments of the present disclosure.

FIG. 2C illustrates a series of conceptual images depicting the alignment and overlay shift determination using rendered design images and segmented SEM images, in accordance with one or more embodiments of the present disclosure.

FIG. 2D illustrates a series of conceptual images depicting the alignment and overlay shift determination using rendered design images and segmented SEM images in a setting where the SEM images include occluded structures, in accordance with one or more embodiments of the present disclosure.

FIG. 3A illustrates an imaging-based optical overlay metrology system for determining overlay measurements using design data and deep learning segmentation, in accordance with one or more embodiments of the present disclosure.

FIG. 3B illustrates an imaging-based SEM overlay metrology system for determining overlay measurements using design data and deep learning segmentation, in accordance with one or more embodiments of the present disclosure.

FIG. 4 illustrates a flowchart depicting a method of measuring overlay using design data and deep learning segmentation, in accordance with one or more embodiments of the present disclosure.

### DETAILED DESCRIPTION

The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure utilize deep learning segmentation to segment images of structures of various layers and then align the segmented images with corresponding rendered design images to calculate overlay shift. Additional embodiments of the present disclosure are directed to determined overlay measurements in settings where occluded structures are present in SEM/optical structures that are observed on the top surface of the sample but are present in the corresponding design file.

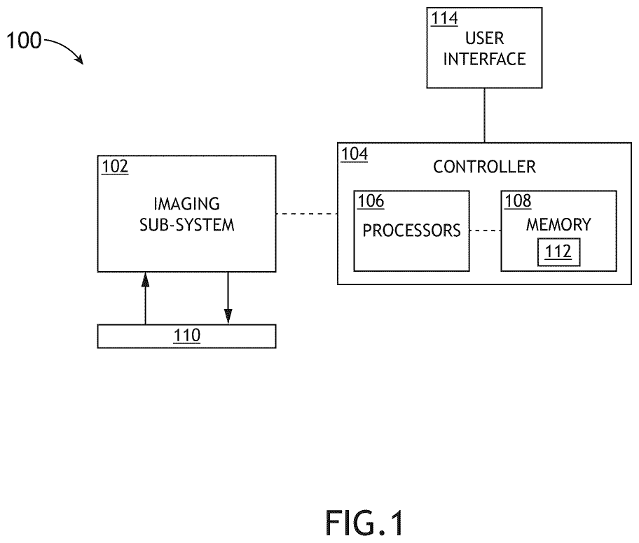

FIG. 1 illustrates a metrology system 100 for overlay measurement utilizing design data and machine learning, in accordance with one or more embodiments of the present disclosure. Metrology system 100 may include any imaging-based overlay metrology system known in the art. For example, the metrology system 100 may include an optical imaging-based metrology system or a charged-particle imaging-based metrology system (e.g., SEM metrology system). The metrology system 100 may include an imaging sub-system 102 and a controller 104. The imaging sub-system 102 may include a light-based optical imaging sub-system or an electron-optical imaging sub-system.

The controller 104 may include one or more processors 106, a memory 108, and a user interface 114. In embodiments, the one or more processors 106 of the controller 104 may be communicatively coupled to memory 108, wherein the one or more processors 106 are configured to execute a set of program instructions stored on memory 108. In embodiments, the controller 104 is communicatively coupled to the optical imaging sub-system 102. In this regard, the one or more processors 106 of the controller 104 may be configured to generate one or more control signals configured to adjust one or more characteristics of the optical imaging sub-system 102 and/or receive measurement data from the optical imaging sub-system 102. In embodiments, the set of program instructions are configured to cause the one or more processors 106 to carry out various functions and steps of the present disclosure.

In embodiments, the one or more processors 106 are configured to receive a user selection of a set of design layers for overlay shift calculation. For example, the one or more processors 106 may receive a user selection of a first design layer and a second design layer (or any number of design layers) from the user interface 114. The user selection may be stored in memory 108.

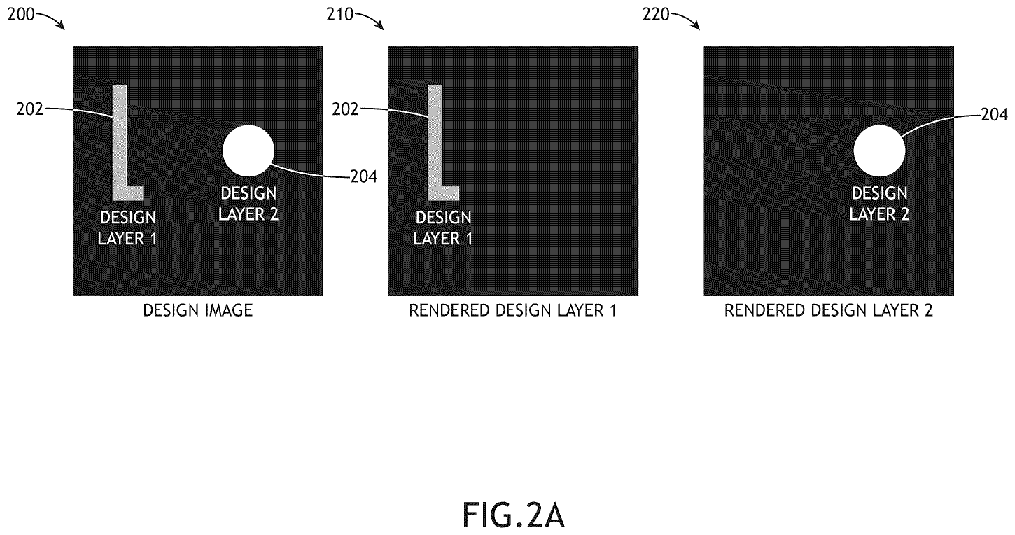

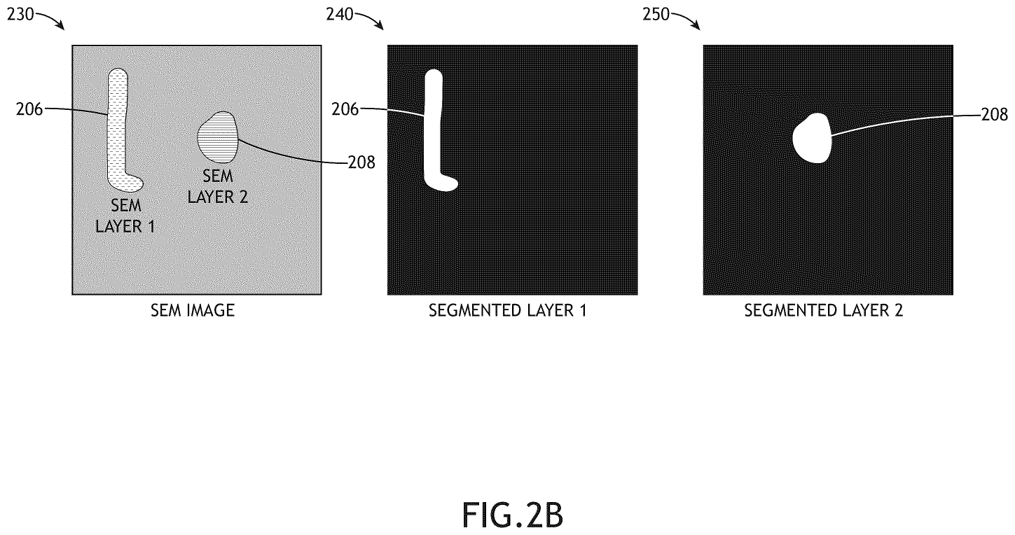

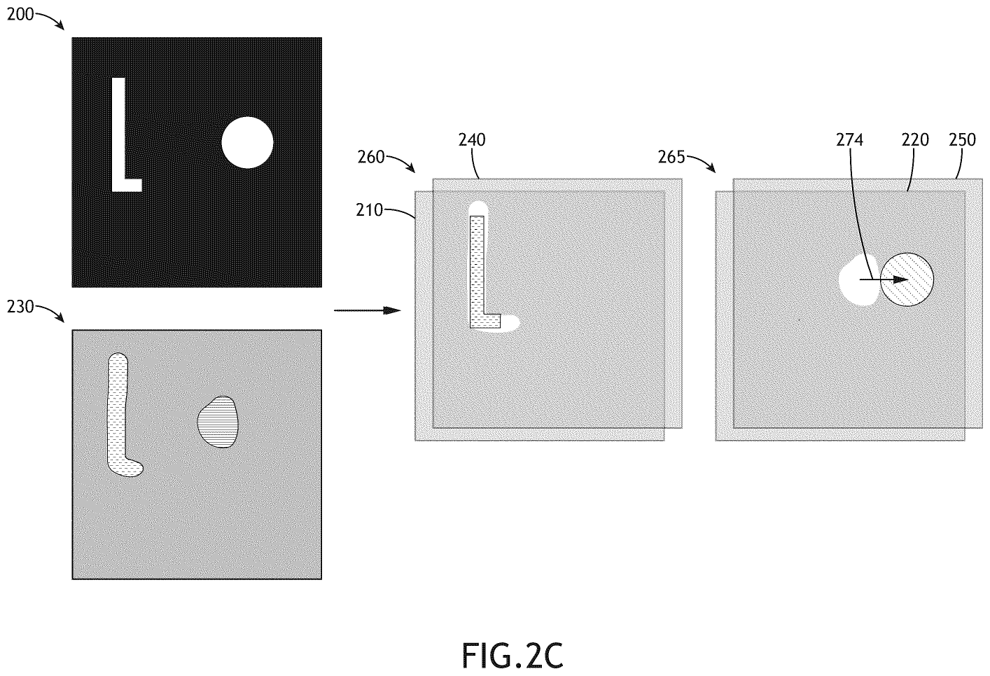

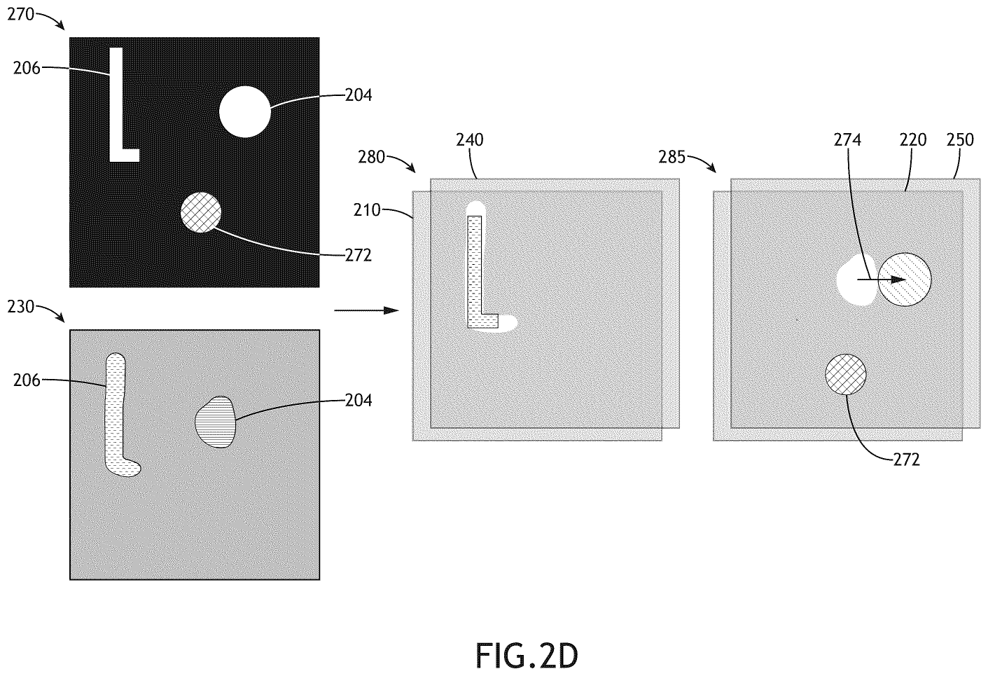

In embodiments, as illustrated in FIG. 2A, the one or more processors 106 are configured to render the set of selected design layers 200 as a set of rendered design images 210, 220. In this example, the set of design layers are shown in image 200 as a first design layer at a first site and a second design layer at a second site. The set of rendered design images 210, 220 correspond to each site 202, 204 within the set of design layers 200. For example, a first design layer may be rendered as a first rendered design image 210 including a first site and a second design layer may be rendered as a second rendered design image 220 including a second site. It is noted the scope of the present disclosure is not limited to two layers or two sites as it is contemplated that any number of layers may be rendered into any number of design images including any number of sites.

In embodiments, as illustrated in FIG. 2B, the one or more processors 106 are configured to acquire one or more measured images 230 of a sample 110 including a set of layers. For example, the set of layers of the sample 110 may include a first layer and a second layer. For instance, in the case of an SEM measurement, the acquired image may include image information associated with a first layer (containing image information for a first site) and a second layer (containing image information for a second site) of the sample 110. The one or more processors 106 of the controller 104 may acquire the one or more images 230 by directing the imaging sub-system 102 to acquire one or more images of the sample 110. In an alternative and/or additional embodiment, the one or more processors 106 may acquire the one or more images 230 from memory 108 (e.g., local or remote memory).

In embodiments, as further illustrated in FIG. 2B, the one or more processors 106 may apply a deep learning model to the one or more measured images 230 to segment the one or more measured images 230 into a first segmented layer 240 containing the first site 206 and a second segmented layer 250 containing the second site 208. In this regard, the deep learning model may segment structures on SEM or optical images for each layer between which overlay shift needs to be measured. In embodiments, one or more training images and the one or more training design images may be used as inputs to train the deep learning model 112. For example, the deep learning model may be trained using a set of training images (e.g., images of known structures) and a set of corresponding design images. For instance, the deep learning model may be trained using SEM or optical images of samples containing known structures on layers for which overlay is to be measured. Once trained, the deep learning model may be applied to new images (e.g., SEM or optical images) to automatically segment measured images 230 into the component layers such as the first segmented layer 240 and the second segmented layer 250 as shown in FIG. 2B. The deep learning model 112 may include any type of machine learning algorithm/classifier and/or deep learning technique or classifier known in the art including, but not limited to, a conditional generative adversarial network (CGAN), a convolutional neural network (CNN) (e.g., GoogleNet, AlexNet, and the like), an ensemble learning classifier, a random forest classifier, artificial neural network (ANN), and the like.

In embodiments, as illustrated in FIG. 2C, the one or more processors 106 align a selected rendered design image with a corresponding segmented layer. In this regard, a user/controller may choose any segmented layer and align it to the corresponding rendered design layer. For example, as shown in image 260 of FIG. 2C, the first rendered design image 210 is aligned with the first segmented layer 240. In addition and/or alternatively, a second rendered design image 220 may be aligned with the second segmented layer 250.

In embodiments, further illustrated in FIG. 2C, the one or more processors 106 determine the overlay shift 274 between the first layer and the second layer based on alignment of the selected rendered design image with the corresponding segmented layer. In embodiments, the overlay shift may be determined using the alignment offset of the first layer and apply it on the second layer and then calculate the alignment offset of the second layer with respect to the corresponding segmented image. For example, the one or more processors 106 may calculate the alignment offset of design polygons of the second layer with respect to the corresponding segmented image. In an additional and/or alternative embodiment, the overlay shift may be determined by aligning the second layer segmented image with the second layer design image using the SEM/optical-to-design offset from the first layer. Then, a centroid calculation may be calculated for both the second segmented layer structures and the second rendered design layer. In this example, the offset between the two centroids represents the overlay shift.

In embodiments, as illustrated in FIG. 2D, the one or more processors 106 may determine overlay shift in cases of occluded structures 272. For example, the one or more processor 106 may determine overlay shift in case where structures are present in a design file image 270 but are not visible on the top surface of the optical or SEM image 230. In embodiments, as discussed previously herein, multiple design images may be rendered and SEM/optical images may be segmented (e.g., segmented using deep learning model).

In embodiments, the one or more processors 106 may apply a centroid-based approach to determine overlay shift in the presence of occluded structures. In this embodiment, the one or more processors 106 may calculate the centroid of each structure in SEM/optical image and the corresponding rendered design image. Then, the one or more processors 106 may calculate centroid shift between nearest structures of SEM/optical image and the corresponding rendered design image. It is noted that this approach may be less effective in settings where the overlay shift is more than the minimum distance of two neighboring structures.

In alternative and/or additional embodiment, the one or more processors 106 may apply an alignment-based approach. In embodiments, the one or more processors 106 may align rendered design images and corresponding segmented SEM/optical images. It is noted that an alignment score may be lower than normal since all structures present in the design layer are not present in the segmented SEM/optical image. In addition, the alignment peak selection may be restricted within a selected radius to ensure far off alignment offsets are not selected.

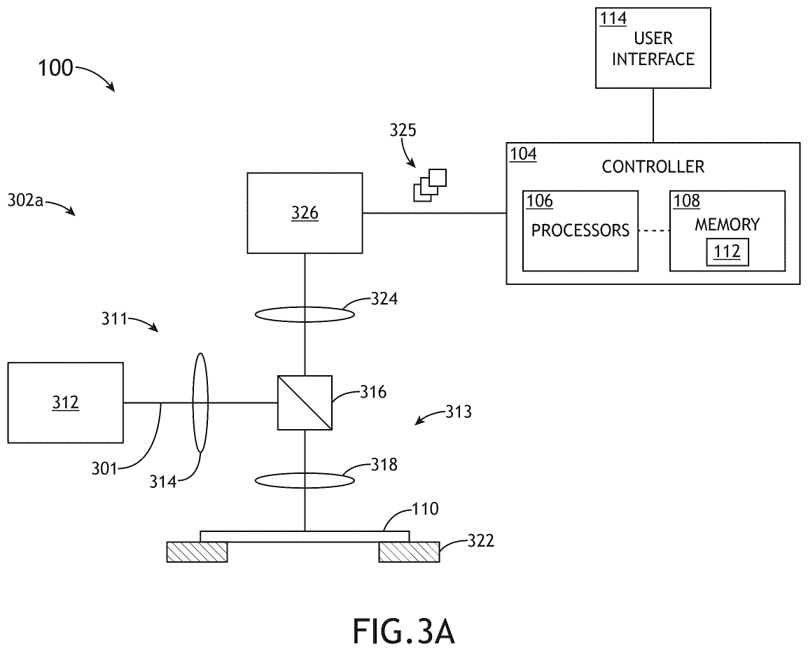

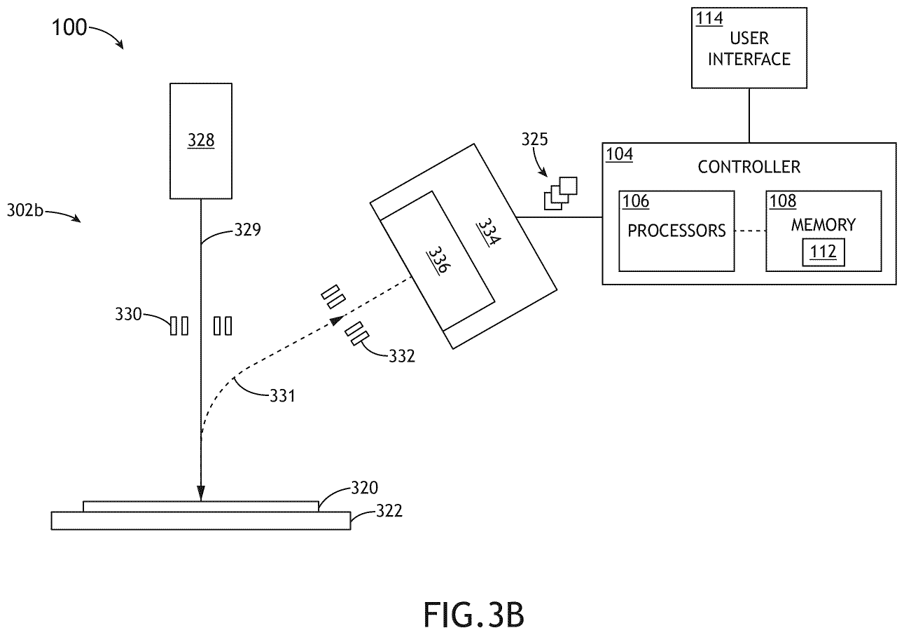

FIG. 3A illustrates a simplified schematic view of the system 100 for determining overlay using design data and deep learning segmentation, in accordance with one or more embodiments of the present disclosure. The system 100 includes optical imaging sub-system 302a and controller 104. The optical imaging sub-system 302a may include any optical-based imaging system known in the art including, but not limited to, an image-based metrology tool. The optical imaging sub-system 302a may include, but is not limited to, an illumination source 312, an illumination arm 311, a collection arm 313, and a detector assembly 326.

In embodiments, optical imaging sub-system 302a is configured to image the sample 110 disposed on the stage assembly 322. Illumination source 312 may include any illumination source known in the art for generating illumination 201 including, but not limited to, a broadband light source or narrowband light source. It is noted that optical imaging sub-system 302a may be configured in any orientation known in the art including, but not limited to, a dark-field orientation, a light-field orientation, and the like.

Sample 110 may include any sample known in the art including, but not limited to, a wafer, a reticle, a photomask, a printed circuit board, a display, and the like. In one embodiment, sample 110 is disposed on a stage assembly 322, to facilitate movement of sample 110 and may operate in any scanning mode known in the art.

The illumination arm 311 may include any number and type of optical components known in the art. In embodiments, the illumination arm 311 includes one or more optical elements 314, a beam splitter 316, and an objective lens 318. In this regard, illumination arm 311 may be configured to focus illumination 301 from the illumination source 312 onto the surface of the sample 110. The one or more optical elements 314 may include any optical elements known in the art including, but not limited to, one or mirrors, one or more lenses, one or more polarizers, one or more beam splitters, and the like.

The collection arm 313 may be configured to collect illumination reflected or scattered from sample 110. In embodiments, collection arm 313 may direct and/or focus the reflected and scattered light to one or more sensors of the detector assembly 326 via one or more optical elements 324. The one or more optical elements 324 may include any optical elements known in the art including, but not limited to, one or mirrors, one or more lenses, one or more polarizers, one or more beam splitters, and the like. It is noted that detector assembly 326 may include any sensor and detector assembly known in the art for detecting illumination reflected or scattered from the sample 110. In embodiments, detector assembly 326 is configured to transmit collected imagery and/or metrology data 325 to the controller 104.

FIG. 3B illustrates a simplified schematic view of the system 100 for determining overlay using design data and deep learning segmentation, in accordance with one or more embodiments of the present disclosure. In this embodiment, FIG. 3B illustrates system 300 including an SEM imaging sub-system 302b.

In embodiments, the SEM imaging sub-system 302b is configured to perform one or more measurements on the sample 110. In this regard, the SEM imaging sub-system 302b may be configured to acquire one or more images of the sample 110. The SEM imaging sub-system 302b may include, but is not limited to, electron beam source 328, one or more electron-optical elements 330, one or more electron-optical elements 332, and an electron detector assembly 334 including one or more electron sensors 336.

In embodiments the electron beam source 328 is configured to direct one or more electron beams 329 to the sample 110. The SEM imaging sub-system 302b may include an electron-optical column. In embodiments, the SEM imaging sub-system 302b includes one or more additional and/or alternative electron-optical elements 330 configured to focus and/or direct the one or more electron beams 329 to the surface of the sample 110. In embodiments, SEM imaging sub-system 302b includes one or more electron-optical elements 332 configured to collect secondary and/or backscattered electrons 331 emanated from the surface of the sample 110 in response to the one or more primary electron beams 329. It is noted herein that the one or more electron-optical elements 330 and the one or more electron-optical elements 332 may include any electron-optical elements configured to direct, focus, and/or collect electrons including, but not limited to, one or more deflectors, one or more electron-optical lenses, one or more condenser lenses (e.g., magnetic condenser lenses), one or more objective lenses (e.g., magnetic condenser lenses), and the like.

It is noted that the electron optical assembly of the SEM imaging sub-system 302b is not limited to the electron-optical elements depicted in FIG. 3B, which are provided merely for illustrative purposes. It is further noted that the system 100 may include any number and type of electron-optical elements necessary to direct/focus the one or more electron beams 329 onto the sample 110 and, in response, collect and image the emanated secondary and/or backscattered electrons 331 onto the electron detector assembly 334.

In embodiments, secondary and/or backscattered electrons 331 are directed to one or more sensors 336 of the electron detector assembly 334. The electron detector assembly 334 of the SEM imaging sub-system 302b may include any electron detector assembly known in the art suitable for detecting backscattered and/or secondary electrons 331 emanating from the surface of the sample 110.

In embodiments, the one or more processors 106 of the controller 104 are configured to analyze the output of detector assembly 334. In embodiments, the set of program instructions are configured to cause the one or more processors 106 to analyze one or more characteristics of sample 110 based on imagery data received from the detector assembly 334.

Referring to FIGS. 1-3B, the one or more processors 106 may include any one or more processing elements known in the art. In this sense, the one or more processors 106 may include any microprocessor-type device configured to execute software algorithms and/or instructions. In embodiments, the one or more processors 106 may be embodied in a desktop computer, mainframe computer system, workstation, image computer, parallel processor, or other computer system (e.g., networked computer) configured to execute a program configured to operate the system 100, as described throughout the present disclosure. It should be recognized that the steps described throughout the present disclosure may be carried out by a single computer system or, alternatively, multiple computer systems. Furthermore, it should be recognized that the steps described throughout the present disclosure may be carried out on any one or more of the one or more processors 106. In general, the term “processor” may be broadly defined to encompass any device having one or more processing elements, which execute program instructions from memory 308. Moreover, different subsystems of the system 100 may include processor or logic elements suitable for carrying out at least a portion of the steps described throughout the present disclosure.

The memory 108 may include any data storage medium known in the art suitable for storing program instructions executable by the associated one or more processors 106 and the data received from the imaging sub-system 102, 302a, or 302b. For example, the memory 308 may include a non-transitory memory medium. For instance, the memory 108 may include, but is not limited to, a read-only memory (ROM), a random-access memory (RAM), a magnetic or optical memory device (e.g., disk), a magnetic tape, a solid-state drive and the like. It is further noted that memory 108 may be housed in a common controller housing with the one or more processors 106. In an alternative embodiment, the memory 108 may be located remotely with respect to the physical location of the processors 106, controller 104, and the like. In another embodiment, the memory 108 maintains program instructions for causing the one or more processors 106 to carry out the various steps described through the present disclosure.

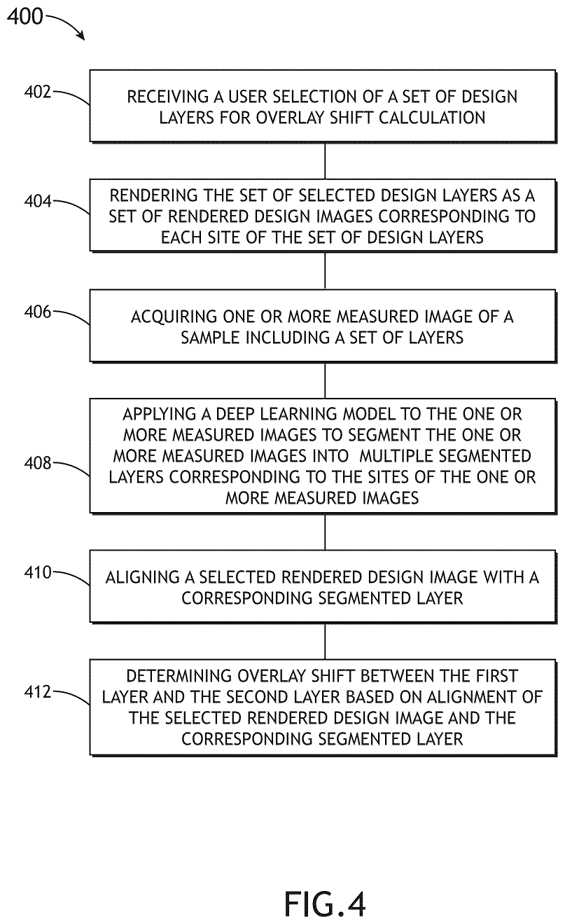

FIG. 4 illustrates a flowchart of a method 400 for determining overlay shift, in accordance with one or more embodiments of the present disclosure. It is noted herein that the steps of method 400 may be implemented all or in part by system 100. It is further recognized, however, that method 400 is not limited to the system 100 in that additional or alternative system-level embodiments may carry out all or part of the steps of method 400.

In embodiments, step 402 of method 400 includes receiving a user selection of a set of design layers for overlay shift calculation. In embodiments, step 404 of method 400 includes rendering the set of selected design layers as a set of rendered design images corresponding to each site of the set of design layers, wherein a first design layer is rendered a first rendered design image including a first site and at least a second design layer is rendered as a second rendered design image including a second site. In embodiments, step 406 of method 400 includes acquiring one or more measured image of a sample including a plurality of layers, wherein the plurality of layers includes a first layer and a second layer. In embodiments, step 408 of method 400 includes applying a deep learning model to the one or more measured images to segment the one or more measured images into at least a first segmented layer containing the first site and a second segmented layer containing the second site. In embodiments, step 410 of method 400 includes aligning a selected rendered design image with a corresponding segmented layer. In embodiments, step 412 of method 400 includes determining overlay shift between the first layer and the second layer based on alignment of the selected rendered design image and the corresponding segmented layer. In embodiments, in an additional step, method 400 includes generating one or more control signals to adjust one or more process tools based on the determined overlay shift. For example, the one or more generated control signals may be configured to adjust one or more upstream and/or downstream process tools (e.g., lithography tool) to mitigate the measured overlay shift in a feedforward and/or feedback loop.

One skilled in the art will recognize that the herein described components (e.g., operations), devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components (e.g., operations), devices, and objects should not be taken as limiting.

Those having skill in the art will appreciate that there are various vehicles by which processes and/or systems and/or other technologies described herein can be effected (e.g., hardware, software, and/or firmware), and that the preferred vehicle will vary with the context in which the processes and/or systems and/or other technologies are deployed. For example, if an implementer determines that speed and accuracy are paramount, the implementer may opt for a mainly hardware and/or firmware vehicle; alternatively, if flexibility is paramount, the implementer may opt for a mainly software implementation; or, yet again alternatively, the implementer may opt for some combination of hardware, software, and/or firmware. Hence, there are several possible vehicles by which the processes and/or devices and/or other technologies described herein may be effected, none of which is inherently superior to the other in that any vehicle to be utilized is a choice dependent upon the context in which the vehicle will be deployed and the specific concerns (e.g., speed, flexibility, or predictability) of the implementer, any of which may vary.

The previous description is presented to enable one of ordinary skill in the art to make and use the invention as provided in the context of a particular application and its requirements. As used herein, directional terms such as “top,” “bottom,” “over,” “under,” “upper,” “upward,” “lower,” “down,” and “downward” are intended to provide relative positions for purposes of description, and are not intended to designate an absolute frame of reference. Various modifications to the described embodiments will be apparent to those with skill in the art, and the general principles defined herein may be applied to other embodiments. Therefore, the present invention is not intended to be limited to the particular embodiments shown and described, but is to be accorded the widest scope consistent with the principles and novel features herein disclosed.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

All of the methods described herein may include storing results of one or more steps of the method embodiments in memory. The results may include any of the results described herein and may be stored in any manner known in the art. The memory may include any memory described herein or any other suitable storage medium known in the art. After the results have been stored, the results can be accessed in the memory and used by any of the method or system embodiments described herein, formatted for display to a user, used by another software module, method, or system, and the like. Furthermore, the results may be stored “permanently,” “semi-permanently,” temporarily,” or for some period of time. For example, the memory may be random access memory (RAM), and the results may not necessarily persist indefinitely in the memory.

It is further contemplated that each of the embodiments of the method described above may include any other step(s) of any other method(s) described herein. In addition, each of the embodiments of the method described above may be performed by any of the systems described herein.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mateable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. A method of overlay measurement comprising:
receiving a user selection of a set of design layers for overlay shift calculation;
rendering the set of selected design layers as a set of rendered design images corresponding to each site of the set of design layers, wherein a first design layer is rendered as a first rendered design image including a first site and at least a second design layer is rendered as a second rendered design image including a second site;
acquiring one or more measured image of a sample including a plurality of layers, wherein the plurality of layers includes a first layer and a second layer;
applying a deep learning model to the one or more measured images to segment the one or more measured images into at least a first segmented layer containing the first site and a second segmented layer containing the second site;
aligning a selected rendered design image with a corresponding segmented layer; and
determining overlay shift between the first layer and the second layer based on alignment of the selected rendered design image and the corresponding segmented layer.

2. The method of claim 1, wherein the one or more measure images comprise at least one of an SEM image or an optical image.

3. The method of claim 1, wherein the aligning a selected rendered design image with a corresponding segmented layer comprises at least one of:
aligning a first rendered design image with the first segmented layer; or
aligning a second rendered design image with the second segmented layer.

4. The method of claim 1, wherein the one or more measurement images include one or more occluded features.

5. The method of claim 1, further comprising:
training the deep learning model using a set of training images and a set of corresponding design images.

6. The method of claim 5, wherein the set of training images comprises at least one of SEM images or optical images.

7. The method of claim 1, wherein the deep learning model comprises a conditional generative adversarial network (CGAN).

8. The method of claim 1, further comprising:
generating one or more control signals to adjust one or more process tools based on the determined overlay shift.

9. A system for overlay measurement comprising:
a controller including one or more processors configured to execute a set of program instructions stored in memory, the set of program instructions configured to cause the one or more processors to:
receive a user selection of a set of design layers for overlay shift calculation;
render the set of selected design layers as a set of rendered design images corresponding to each site of the set of design layers, wherein a first design layer is rendered as a first rendered design image including a first site and at least a second design layer is rendered as a second rendered design image including a second site;
acquire one or more measured image of a sample including a plurality of layers, wherein the plurality of layers includes a first layer and a second layer;
apply a deep learning model to the one or more measured images to segment the one or more measured images into at least a first segmented layer containing the first site and a second segmented layer containing the second site;
align a selected rendered design image with a corresponding segmented layer; and
determine overlay shift between the first layer and the second layer based on alignment of the selected rendered design image with a corresponding segmented layer.

10. The system of claim 9, wherein the one or more measure images comprise at least one of an SEM image or an optical image.

11. The system of claim 9, wherein the aligning a selected rendered design image with a corresponding segmented layer comprises at least one of:
aligning a first rendered design image with the first segmented layer; or
aligning a second rendered design image with the second segmented layer.

12. The system of claim 9, wherein the one or more measurement images include one or more occluded features.

13. The system of claim 9, further comprising:
training the deep learning model using a set of training images and a set of corresponding design images.

14. The system of claim 13, wherein the set of training images comprises at least one of SEM images or optical images.

15. The system of claim 9, wherein the deep learning model comprises a conditional generative adversarial network (CGAN).

16. The system of claim 9, further comprising:
generating one or more control signals to adjust one or more process tools based on the determined overlay shift.

17. A system for overlay measurement comprising:
a imaging sub-system configured to acquire one or more images of a sample; and
a controller including one or more processors configured to execute a set of program instructions stored in memory, the set of program instructions configured to cause the one or more processors to:
receive a user selection of a set of design layers for overlay shift calculation;
render the set of selected design layers as a set of rendered design images corresponding to each site of the set of design layers, wherein a first design layer is rendered as a first rendered design image including a first site and at least a second design layer is rendered as a second rendered design image including a second site;
acquire one or more measured image of a sample including a plurality of layers from the imaging sub-system, wherein the plurality of layers includes a first layer and a second layer;
apply a deep learning model to the one or more measured images to segment the one or more measured images into at least a first segmented layer containing the first site and a second segmented layer containing the second site;
align each rendered design image with a corresponding segmented layer, wherein a first rendered design image is aligned with the first segmented layer and a second rendered design image is aligned with the second segmented layer; and
determine overlay shift between the first layer and the second layer based on alignment of the first rendered design image with the first segmented layer and the second rendered design image with the second segmented layer.

18. The system of claim 17, wherein the imaging sub-system comprises at least one of a scanning electron microscopy (SEM) or an optical imaging system.

19. The system of claim 17, wherein the one or more measurement images include one or more occluded features.

20. The system of claim 17, further comprising:
training the deep learning model using a set of training images and a set of corresponding design images.
